(19) United States
(12) Patent Application Publication
(10) Pub. No.: US 2026/0231482 A1
(43) Pub. Date: Aug. 6, 2026

(54) POWER SEMICONDUCTOR DEVICE

(71) Applicant: HYUNDAI MOBIS CO., LTD., Seoul (KR)

(72) Inventor: Mingi KANG, Yongin-si (KR)

(73) Assignee: HYUNDAI MOBIS CO., LTD., Seoul (KR)

(21) Appl. No.: 19/364,030

(22) Filed: Oct. 21, 2025

(30) Foreign Application Priority Data
Jan. 31, 2025 (KR) 10-2025-0012300
Mar. 28, 2025 (KR) 10-2025-0040064

(51) Int. Cl. H10D 62/10; H10D 30/66; H10D 62/832; H10D 64/27

(52) U.S. Cl. CPC H10D 62/107; H10D 30/668; H10D 62/8325; H10D 64/513; H10D 64/516

(57) ABSTRACT

According to one embodiment, there is provided a power semiconductor device including a first electrode, a semiconductor layer on the first electrode, a second electrode on the semiconductor layer, and a plurality of gate electrodes on the semiconductor layer, wherein the semiconductor layer includes a first semiconductor layer of a first conductivity type on the first electrode, and a second semiconductor layer of a second conductivity type between the first semiconductor layer and the second electrode, the second electrode includes a 2-1 electrode extending in a first direction, and a plurality of 2-2 electrodes spaced apart from each other in the first direction, the second semiconductor layer or the first semiconductor layer includes a trench region, the trench region is disposed between the plurality of 2-2 electrodes, and the gate electrodes are disposed in the trench region.

### CROSS REFERENCE TO RELATED APPLICATION

This patent document claims the priority and benefits of Korean Patent Application No. 10-2025-0012300, filed January 31, 2025, and also Korean Patent Application No. 10-2025-0040064, filed March 28, 2025, the entire contents of which is incorporated herein for all purposes by this reference.

### Technical Field

Embodiments of the disclosed technology relate to a power semiconductor device.

### Background

Power semiconductor devices are semiconductor devices that operate in high voltage and high current environments. The power semiconductor devices are used in fields that require high power switching, such as power conversion, power converters, inverters, etc. For example, the power semiconductor device may include insulated gate bipolar transistors (IGBTs), power metal oxide semiconductor field effect transistors (MOSFETs), etc. The power semiconductor devices basically require high voltage withstand characteristics, and recently, have additionally required a high-speed switching operation.

Accordingly, power semiconductor devices using silicon carbide (SiC) instead of existing silicon (Si) are being studied. Silicon carbide (SiC) is a wide-gap semiconductor material with a higher bandgap than silicon and can maintain stability even at high temperatures compared to silicon. Furthermore, silicon carbide has a much higher breakdown voltage than silicon, and thus can operate stably even at high voltages. Accordingly, silicon carbide has a higher breakdown voltage than silicon and also has excellent heat dissipation, thereby exhibiting operable characteristics at high temperatures.

### SUMMARY

Embodiments of the present specification are directed to providing a power semiconductor device capable of improving the electrical and physical stability of a lower portion of a gate.

Embodiments of the present specification are directed to providing a power semiconductor device capable of reducing energy loss by minimizing an increase in resistance.

Objects of the present specification are not limited to the above-described objects, and other technical objects may be inferred from the following embodiments.

In order to achieve the above objects, according to one embodiment, there is provided a power semiconductor device including a first electrode, a semiconductor layer on the first electrode, a second electrode on the semiconductor layer, and a plurality of gate electrodes on the semiconductor layer, wherein the semiconductor layer includes a first semiconductor layer of a first conductivity type on the first electrode, and a second semiconductor layer of a second conductivity type between the first semiconductor layer and the second electrode, the second electrode includes a 2-1 electrode extending in a first direction, and a plurality of 2-2 electrodes spaced apart from each other in the first direction, the second semiconductor layer or the first semiconductor layer includes a trench region, the trench region is disposed between the plurality of 2-2 electrodes, and the gate electrodes are disposed in the trench region.

Detailed matters of other embodiments are included in the detailed description and accompanying drawings.

### BRIEF DESCRIPTION OF THE DRAWINGS

FIG. 1 is a view of a power semiconductor device according to one embodiment.

FIG. 2 is a view showing a semiconductor layer of FIG. 1.

FIG. 3 is a view showing a flow of electrons in the semiconductor layer of FIG. 2.

FIG. 4 is a view of a power semiconductor device according to another embodiment.

FIG. 5 is a view of a power semiconductor device according to still another embodiment.

FIG. 6 is a cross-sectional view showing area Q1 of FIG. 3.

### DETAILED DESCRIPTION OF THE DISCLOSURE

Hereinafter, embodiments will be described with reference to the accompanying drawings.

The same reference numerals indicate the same components. In addition, in the drawings, thicknesses, proportions, and dimensions of components can be exaggerated for effective description of technical contents. Scales of components illustrated in the drawings differ from the actual scale for convenience of description, and thus are not limited to the scales illustrated in the drawings.

In the specification, when a certain component (or an area, a layer, a portion, etc.) is described as “on,” “connected,” or “coupled to” another component, it means that the certain component may be directly connected/coupled to another component or still another component may be disposed therebetween.

The term “and/or” includes all one or more combinations that may be defined by the associated configurations.

The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings. For example, as long as “immediately” or “directly” is not used, one or more other portions may be positioned between two portions. The spatially relative terms “below or beneath,” “lower,” “above,” “upper,” etc. can be used to easily describe the correlation with one element or components and another element or components as shown in the drawings. The spatially relative terms should be understood as including different directions of elements in use or operation in addition to the directions shown in the drawings. For example, in case of turning the element shown in the drawing upside down, an element described as being disposed “below” or “beneath” another element may be disposed “above” another element. Accordingly, the exemplary term “below” may include both downward and upward directions.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

Features of various embodiments of the present specification may be coupled or combined partially or entirely, various technological interworking and driving are made possible, and the embodiments may be implemented independently of each other or implemented together in an associated relationship.

Hereinafter, a power semiconductor device of the present specification will be described with reference to the accompanying drawings and embodiments as follows.

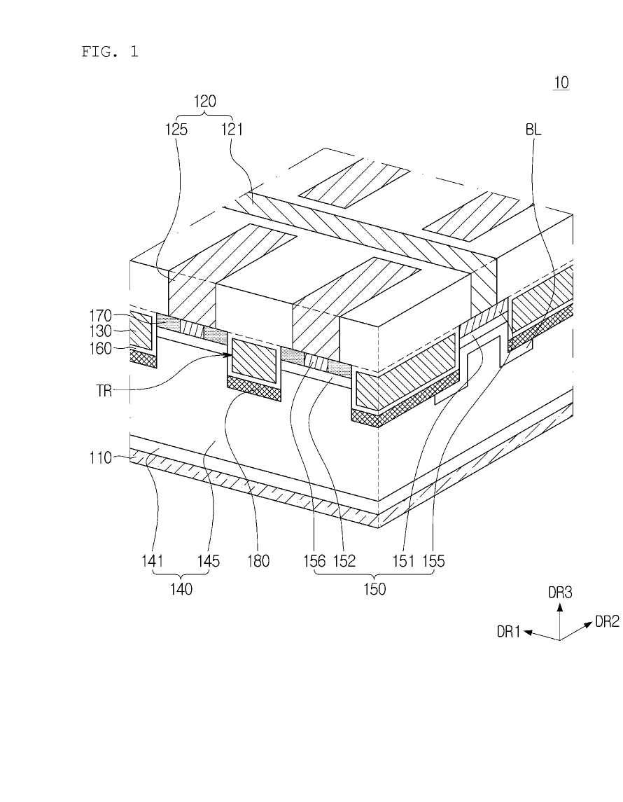

FIG. 1 is a view of a power semiconductor device according to one embodiment.

Referring to FIG. 1, a power semiconductor device according to one embodiment may include a first electrode 110, a second electrode 120 facing the first electrode 110, and a plurality of components 130, 140, 150, 160, 170, and BL between the first electrode 110 and the second electrode 120. A portion of the power semiconductor device is shown in FIG. 1, but a plurality of power semiconductor devices may be disposed.

The first electrode 110 may be a drain electrode, and the second electrode 120 may be a source electrode, but embodiments of the present specification are not limited thereto, and the two electrodes may be opposite to each other. The first electrode 110 and the second electrode 120 may include a conductive material. For example, the conductive material may be a metal, but the embodiments of the present specification are not limited thereto.

The second electrode 120 may include a 2-1 electrode 121 and a 2-2 electrode 125. The 2-1 electrode 121 may extend in a first direction DR1, the 2-2 electrode 125 may be provided as a plurality of electrodes, and the plurality of 2-2 electrodes 125 may be disposed to be spaced apart from each other in the first direction DR1. Each of the plurality of 2-2 electrodes 125 may extend in a second direction DR2 with respect to the 2-1 electrode 121. That is, an extension direction of the 2-1 electrode 121 and an extension direction of the 2-2 electrode 125 may intersect or be perpendicular. The 2-1 electrode 121 may be provided as a plurality of electrodes, and the plurality of 2-2 electrodes 125 may be disposed between the plurality of 2-1 electrodes 121.

The 2-1 electrode 121 may be in direct contact with a 1-1 source layer 155. The 2-1 electrode 121 may be surrounded by an insulating layer 160 and a portion of a lower portion thereof may be exposed. The 2-1 electrode 121 may be in direct contact with the 1-1 source layer 155 through the exposed lower portion.

The 2-2 electrode 125 may be in direct contact with a 1-2 source layer 156 and a second source layer 170. The 2-2 electrode 125 may be surrounded by the insulating layer 160, but a lower portion thereof may be exposed. The 2-2 electrode 125 may be in direct contact with the 1-2 source layer 155 and the second source layer 170 through the exposed lower portion. Current may flow through a region in which the 2-2 electrode 125 is in direct contact with the second source layer 170. Between adjacent gate electrodes 130 in a cross-sectional view, two second source layers 170 may be present, and one 1-2 source layer 155 may be disposed between the two second source layers 170.

The 2-1 electrode 121 and the 2-2 electrode 125 may be electrically connected. In the drawing, the 2-1 electrode 121 and the 2-2 electrode 125 are shown as being spaced apart from each other, but actually, a separate conductive layer is present on the electrodes, and the 2-1 electrode 121 and the 2-2 electrode 125 may be electrically connected through the conductive layer.

Thicknesses of the 2-1 electrode 121 and the 2-2 electrode 125 may be the same, but the embodiments of the present specification are not limited thereto.

In a plan view (when viewed from the top to the bottom), the gate electrode 130 may be disposed around the plurality of 2-2 electrodes 125 spaced apart from each other. For example, the gate electrode 130 may be provided as a plurality of gate electrodes, and the plurality of gate electrodes 130 may be disposed in a form that surrounds the 2-2 electrodes 125 spaced apart from each other, respectively, from all sides. The plurality of gate electrodes 130 may be electrically connected.

As the plurality of 2-2 electrodes 125 are disposed to be spaced apart from each other in the first direction DR1, the plurality of gate electrodes 130 may also be connected and disposed in the first direction DR1. The plurality of gate electrodes 130 connected and disposed in the first direction DR1 may be disposed symmetrically with the 2-1 electrode 121 interposed therebetween and disposed to be spaced apart from each other in the second direction DR2.

A second layer 145, a third layer 151, a 1-2 source layer 156, and the second source layer 170 may be disposed between the plurality of gate electrodes 130 spaced apart from each other in the first direction DR1, and the second layer 145, a bonding layer BL, a third layer 152, and the 1-1 source layer 155 may be disposed between the plurality of gate electrodes 130 spaced apart from each other in the second direction DR2.

The gate electrode 130 may include a conductive material. For example, the conductive material may be a metal or poly silicon, but the embodiments of the present specification are not limited thereto.

The gate electrode 130 may be completely surrounded by the insulating layer 160.

The insulating layer 160 may insulate a semiconductor layer adjacent to the gate electrode 130. Examples of the insulating layer 160 may include silicon oxide (SiO₂), silicon nitride (SiNₓ), silicon oxynitride (SiON), etc., but the embodiments of the present specification are not limited thereto.

Semiconductor layers 140, 150, 170, 180, and BL between the first electrode 110 and the second electrode 120 may include silicon carbide (SiC) and have different conductivity types or different doping concentrations. Silicon carbide (SiC) may have high withstand voltage characteristics. The semiconductor layers 140, 150, 170, 180, and BL may include a first semiconductor layer 140, a second semiconductor layer 150 on the first semiconductor layer 140, the source layer 170 on the second semiconductor layer, a protective layer 180 disposed between the first semiconductor layer 140 and the second semiconductor layer 150, and a bonding layer BL.

The first semiconductor layer 140 may be disposed on the first electrode 110. The first semiconductor layer 140 may include a first layer 141 and a second layer 145. The first layer 141 may be directly disposed on the first electrode 110, and the second layer 145 may be directly disposed on the first layer 141. The first semiconductor layer 140 may have a first conductivity type, and the first conductivity type may be N-type.

The doping concentration of the first layer 141 may be higher than the doping concentration of the second layer 145. Since the doping concentration of the first layer 141 is higher than the doping concentration of the second layer 145, a junction resistance between the first electrode 110 and the first semiconductor layer 140 can be reduced.

The second layer 145 may be disposed between adjacent gate electrodes 130. That is, the second layer 143 may be located on the first layer 141 and may have a shape that protrudes upward (e.g., in the third direction DR3) in a region in which the gate electrode 130 is not disposed.

A plurality of trench regions TR may be formed in the plurality of components 140, 150, and 160 between the first electrode 110 and the second electrode 130. The trench regions TR may be disposed around the 2-2 electrode 125 in a plan view and provided as a plurality of regions. The plurality of trench regions TR may be disposed side by side in the first direction DR1 and connected. The plurality of connected trench regions TR may be disposed symmetrically to be spaced apart from each other with the 2-1 electrode 121 interposed therebetween. The gate electrode 130 may be disposed within the trench region TR.

The trench region TR may recess the second layer 145, the third layer 151, the 1-1 source layer 155, the second source layer 156, and the insulating layer 160 in a thickness direction. The protective layer 180 may be disposed under the trench region TR. A width of the protective layer 180 may be the same as a width of the trench region TR. However, the embodiments of the present specification are not limited thereto, and the protective layer 180 may cover a portion of a side portion of the trench region TR.

The second semiconductor layer 150 may have a second conductivity type, and the second conductivity type may be P-type. The second semiconductor layer 150 may include the third layer 151 and 152 and the first source layer 155 and 156.

The third layer 151 and 152 may be disposed on the second layer 145. The third layer 151 and 152 may include the 3-1 layer 151 located below the 2-1 electrode 121 and the 3-2 layer 152 located below the 2-2 electrode 125 in a plan view.

The bonding layer BL may be disposed between the 3-1 layer 151 and the second layer 145, and the 1-1 source layer 155 may be disposed on the 3-1 layer 151. The 3-1 layer 151 may be in direct contact with the bonding layer BL and the 1-1 source layer 155.

On the 3-2 layer 152, the 1-2 source layer 156 and the second source layer 170 may be disposed, and the 3-2 layer 152 may be in direct contact with the second layer 145 downward and may be in direct contact with the 1-2 source layer 156 and the second source layer 170 upward. Current may flow through a region in which the 3-2 layer 152 is in direct contact with the second source layer 170.

Side surfaces of the third layer 151 and 152 may be in direct contact with the insulating layer 160. The insulating layer 160 may insulate the third layer 151 and 152 and the gate electrode 130.

The first source layer 155 and 156 may be disposed on the third layer. The first source layer 155 and 156 may include the 1-1 source layer 155 disposed on the 3-1 layer 151, and the 1-2 source layer 156 disposed on the 3-2 layer 152.

A lower portion of the 1-1 source layer 155 may be in direct contact with the 3-1 layer 151, an upper portion thereof may in direct contact with the 2-1 electrode 121, and side surfaces thereof may be in direct contact with the insulating layer 160.

A lower portion of the 1-2 source layer 156 may be in direct contact with the 3-2 layer 152, an upper portion thereof may in direct contact with the 2-2 electrode 125, and side surfaces thereof may be in direct contact with the second source layer 170.

The doping concentration of the first source layer 155 and 156 may be higher than the doping concentration of the third layer 151 and 152. Since the doping concentration of the first source layer 155 and 156 is higher, there is an advantage that contact resistance at the contact surface with the second electrode 120 can be reduced.

The protective layer 180 has a second conductivity type, and the second conductivity type may be P-type. The doping concentration of the protective layer 180 may be higher than the doping concentration of the third layer 151 and 152.

The protective layer 180 may be disposed between the second layer 145 and the gate electrode 130. A lower surface and side surfaces of the protective layer 180 may be in direct contact with the second layer 145, and an upper surface thereof may be in direct contact with the gate electrode 130 or the insulating layer 160 surrounding the gate electrode 130.

The bonding layer BL has a second conductivity type, and the second conductivity type may be P-type. The doping concentration of the bonding layer BL may be higher than the doping concentration of the third layer 151 and 152, but the embodiments of the present specification are not limited thereto.

The bonding layer BL may be disposed between the second layer 145 and the 3-1 layer 151 and/or the protective layer 180 and may be in direct contact with adjacent components 145, 151, and 180. For example, the bonding layer BL may be disposed in a form that overlaps both the lower portion of the protective layer 180 and the lower portion of the 3-1 layer 151, disposed in a form that is in contact with only the lower portion of the 3-1 layer 151, or disposed in a form that is in contact with only the lower portion of the protective layer 180. The bonding layer BL may also be disposed in regions of side surfaces that are in direct contact with the second layer 145, in which the trench region TR, the 3-1 layer 151, and the 1-1 source layer 155 meet. That is, the bonding layer BL may also be disposed between the side surfaces of the insulating layer 160 surrounding the trench region TR and the second layer 145. For example, in a plan view formed by the second direction DR2 and the third direction DR3, a cross-sectional shape of the bonding layer BL may be an ohm (Ω) shape, but the embodiments of the present specification are not limited thereto.

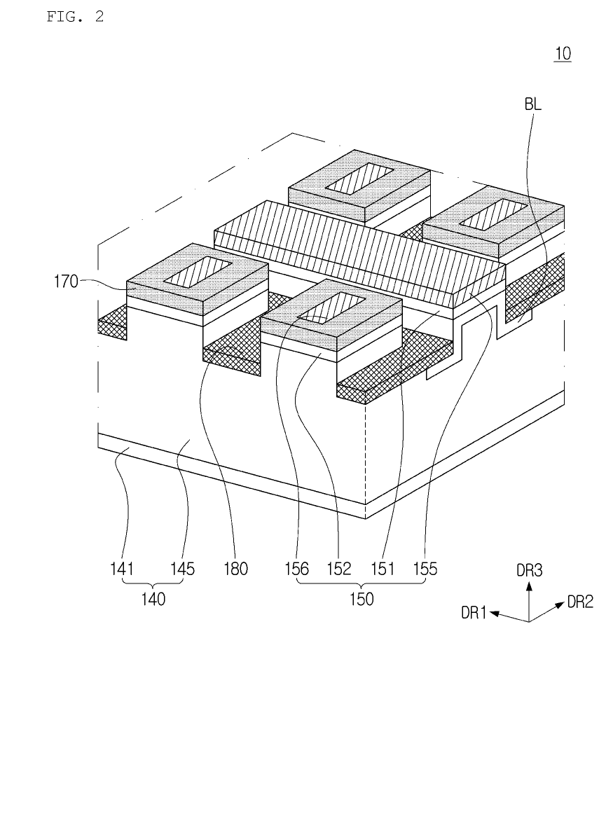

FIG. 2 is a view showing a semiconductor layer of FIG. 1.

FIG. 2 is a view showing the components 140, 150, 170, and BL of the semiconductor layer formed between the first electrode 110 (see FIG. 1) and the insulating layer 160 (see FIG. 1) and is introduced to describe an internal structure of the semiconductor layers 140, 150, 170, and BL.

Referring to FIG. 2, the 1-1 source layer 155 may extend in the first direction DR1, the 1-2 source layer 156 and the second source layer 170 may be provided as a plurality of layers, and the plurality of 1-2 source layers 156 and the second source layers 170 may be disposed to be spaced apart from each other in the first direction DR1. Each of the plurality of 1-2 source layers 156 and second source layers 170 may extend in the second direction DR2 with respect to the 1-1 source layer 155. That is, an extension direction of the 1-1 source layer 155 and an extension direction of the 1-2 source layer 156 and the second source layer 170 may intersect or be perpendicular. The 1-1 source layer 155 may be provided as a plurality of layers, and the plurality of 1-2 source layers 156 and second source layers 170 may be disposed between the plurality of 1-1 source layers 155.

The thicknesses of the 1-1 source layer 155, the 1-2 source layer 156, and the second source layer 170 may be the same, but the embodiments of the present specification are not limited thereto.

The second source layer 170 may be disposed in a form that surrounds the 1-2 source layer 156 from all sides. Accordingly, an area in which an upper surface of the second source layer 170 is in direct contact with the 2-2 electrode 125 (see FIG. 1) may be formed in a form that surrounds the 1-2 source layer 156 from all sides, and current may also flow through the area in a form that surrounds the 1-2 source layer 156 from all sides.

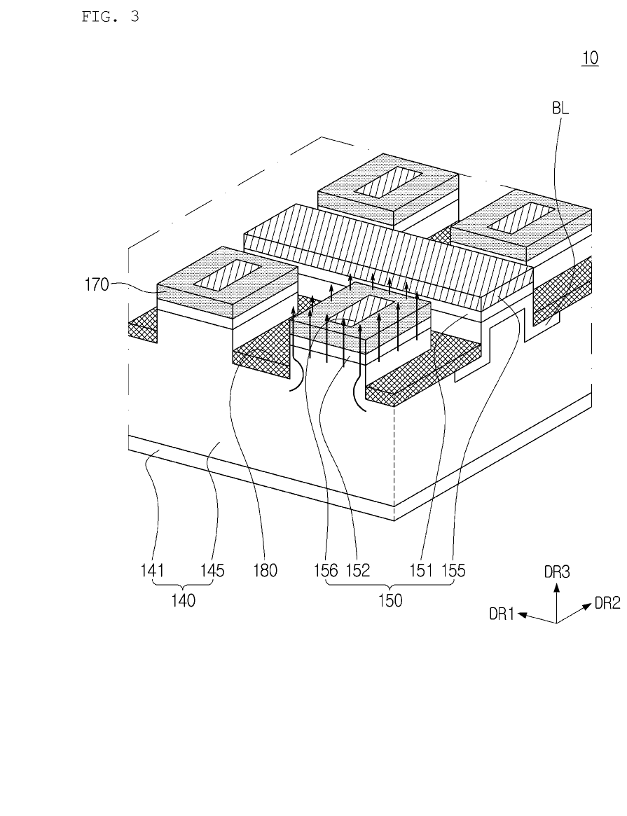

FIG. 3 is a view showing a flow of electrons in the semiconductor layer of FIG. 2.

Referring to FIG. 3, depending on a voltage applied to the gate electrode 130 (see FIG. 1), a channel may be formed along side surfaces where the gate electrode 130 (see FIG. 1) and the 3-2 layer 152 are in contact. For example, when a positive voltage higher than a threshold voltage (VTH) is applied to the gate electrode 130 (see FIG. 1), a channel may be formed in the 3-2 layer 152 around the gate electrode 130 (see FIG. 1).

Electrons may move from the first electrode 110 (see FIG. 1) to the second source layer 170 through the channel formed by the 3-2 layer 152 and the gate electrode 130 (see FIG. 1). The second source layer 170 may be in direct contact with the 2-2 layer 125.

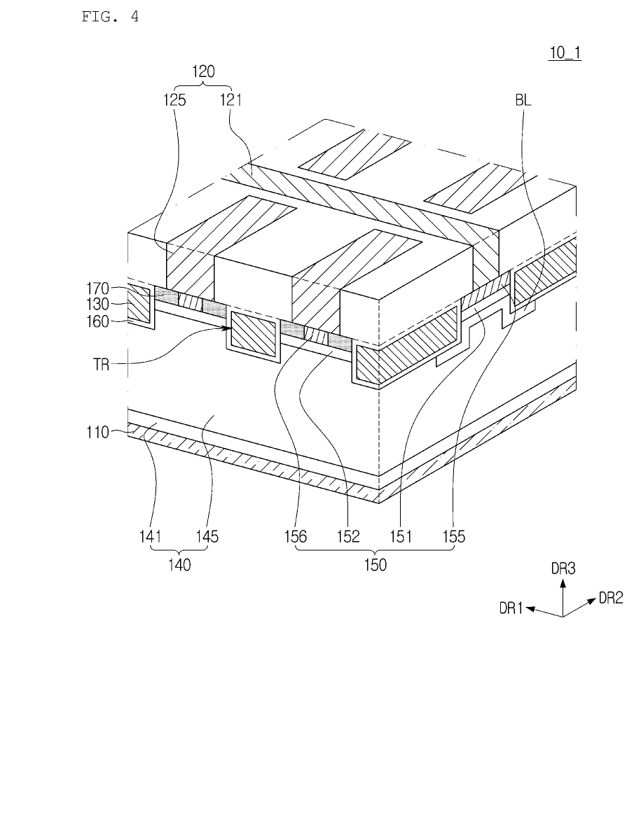

FIG. 4 is a view of a power semiconductor device according to another embodiment.

Referring to FIG. 4, a power semiconductor device 10_1 according to another embodiment differs from the semiconductor device 10 according to FIG. 1 in that it does not include the protective layer 180 (see FIG. 1).

An upper surface of the bonding layer BL may be disposed to overlap a lower surface of the 3-1 layer 151 and a lower surface of the insulating layer 160 surrounding the gate electrode 130 and may be in direct contact with the corresponding components 151 and 160.

The plurality of 2-1 electrodes 121 extending in the first direction DR1 may be disposed to be spaced apart from each other in the second direction DR2, and the plurality of gate electrodes 130 may be disposed between the 2-1 electrodes 121 spaced apart from each other, and since the plurality of gate electrodes 130 are disposed to surround the plurality of 2-1 electrodes 121 from all sides in a plan view, the bonding layer BL disposed below the plurality of gate electrodes 130 may also extend in the first direction DR1.

Accordingly, even when the protective layer 180 (see FIG. 1) is not disposed, by adjusting a distance between the plurality of 2-1 electrodes 121, an electric field below the plurality of gate electrodes 130 may be adjusted and stabilized.

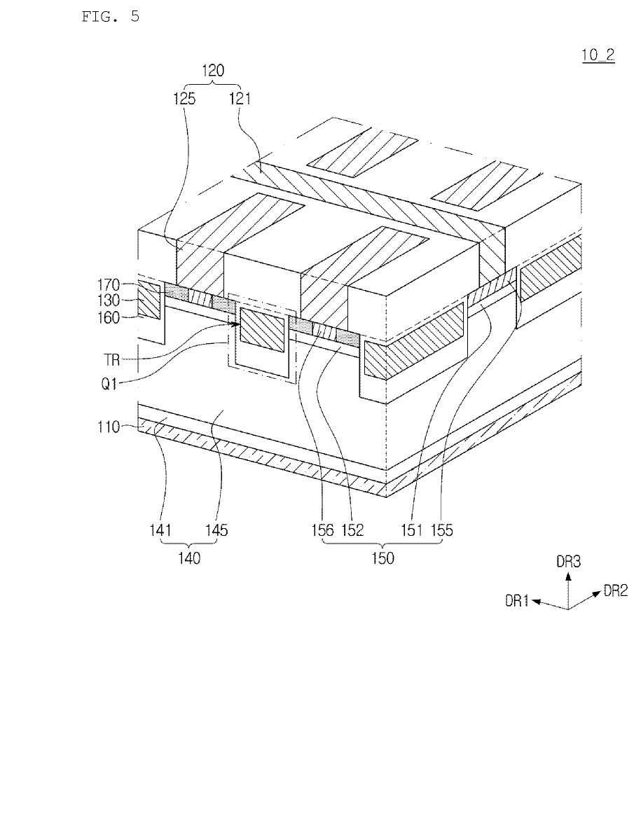

FIG. 5 is a view of a power semiconductor device according to still another embodiment.

Referring to FIG. 5, a power semiconductor device 10_2 according to still another embodiment differs from the power semiconductor device 10 according to one embodiment in that the thickness of the insulating layer 160 surrounding the gate electrode 130 differs by region.

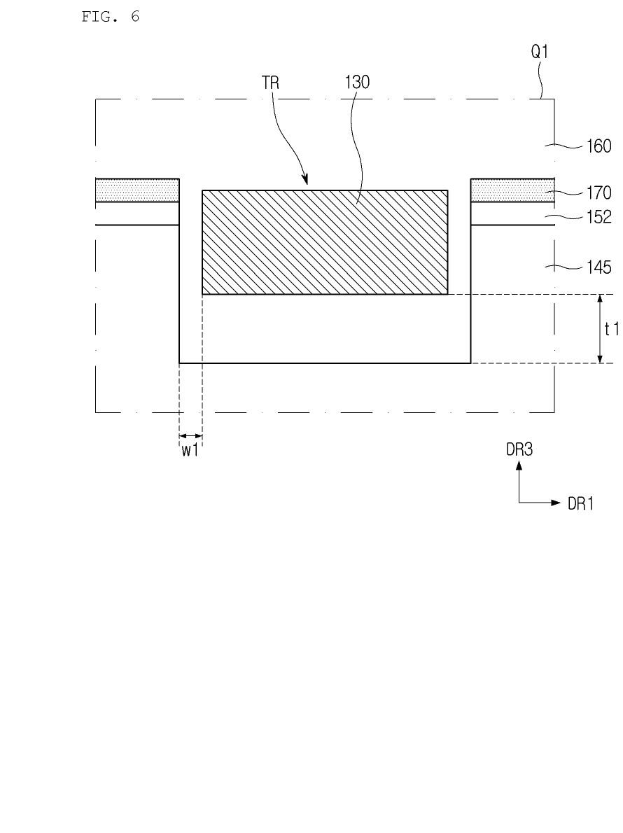

The insulating layer 160 may completely surround the gate electrode 130. When the thickness of the insulating layer 160 increases, the electric field may be dispersed while passing through the insulating layer 160, thereby increasing an electric field margin and improving the operational reliability of the power semiconductor device 10-2. However, as the thickness of the insulating layer 160 increases, the resistance of a channel formed in the 3-2 layer 152 by the gate electrode 130 to be described below may increase. Accordingly, when only the thickness of the insulating layer 160 disposed below the gate electrode 130 in which the channel is not formed (e.g., the other side in a third direction DR3) is formed thicker, it is possible to increase the electric field margin without increasing the resistance of the channel. The detailed description of the thickness of the insulating layer 160 will be described below in FIG. 6.

FIG. 6 is a cross-sectional view showing area Q1 of FIG. 5.

Referring to FIG. 6, the insulating layer 160 may completely surround the gate electrode 130. The insulating layer 160 disposed along the side surfaces of the gate electrode 130 may be in direct contact with the second source layer 170, the 3-2 layer 152, and the second layer 145 and may insulate each layer from the gate electrode 130.

When voltage is applied to the gate electrode 130, a channel may be formed along the region of the 3-2 layer 152 that is in contact with the insulating layer 160. Accordingly, electrons in the second layer 145 and the second source layer 170 may move through the channel formed in the 3-2 layer 152. In this case, when a width w1 of the insulating layer 160 in the first direction DR1 that is in contact with the 3-2 layer 152 increases, the resistance of the channel formed in the 3-2 layer 152 may increase.

On the other hand, the insulating layer 160 disposed below the gate electrode 130 may be in direct contact with only the second layer 145. Accordingly, even when voltage is applied to the gate electrode 130, a channel may not be formed below the gate electrode 130.

Accordingly, thicknesses of the insulating layer 160 disposed on the side surfaces of the gate electrode 130 and the insulating layer 160 disposed below the gate electrode 130 may need to be formed differently. That is, the insulating layer 160 disposed on the side surfaces of the gate electrode 130 may need to be formed thinly to minimize an increase in resistance of the channel, and the insulating layer 160 disposed under the gate electrode 130 may need to be formed thickly to increase the electric field margin, thereby improving the overall electrical and physical stability of the device.

For example, a thickness t1 of the insulating layer 160 disposed below the gate electrode 130 in the third direction DR3 may be larger than the width w1 of the insulating layer 160 disposed on the side surfaces of the gate electrode 130 in the first direction DR1. Accordingly, the resistance of the channel formed in the 3-2 layer 152 may not be increased, and at the same time, the electric field margin may be increased below the gate electrode 130.

A power semiconductor device according to various embodiments of the present specification may be described as follows.

According to various embodiments of the present disclosure, a power semiconductor device includes a first electrode, a semiconductor layer on the first electrode, a second electrode on the semiconductor layer, and a plurality of gate electrodes on the semiconductor layer, wherein the semiconductor layer includes a first semiconductor layer of a first conductivity type on the first electrode, and a second semiconductor layer of a second conductivity type between the first semiconductor layer and the second electrode, the second electrode includes a 2-1 electrode extending in a first direction, and a plurality of 2-2 electrodes spaced apart from each other in the first direction, the second semiconductor layer or the first semiconductor layer includes a trench region, the trench region is disposed between the plurality of 2-2 electrodes, and the gate electrodes are disposed in the trench region.

According to the power semiconductor device according to various embodiments of the present specification, the first semiconductor layer and the second semiconductor layer may include silicon carbide (SiC).

According to the power semiconductor device according to various embodiments of the present specification, the first conductivity type may be an N type.

According to the power semiconductor device according to various embodiments of the present specification, the second conductivity type may be a P type.

According to the power semiconductor device according to various embodiments of the present specification, the first semiconductor layer may include a first layer and a second layer on the first layer, and a doping concentration of the first layer may be higher than a doping concentration of the second layer.

According to the power semiconductor device according to various embodiments of the present specification, the second semiconductor layer may include a third layer and a first source layer between the third layer and the second electrode, the first source layer may have the second conductivity type, and a doping concentration of the third layer may be lower than a doping concentration of the first source layer.

According to the power semiconductor device according to various embodiments of the present specification, the 2-1 electrode and the plurality of 2-2 electrodes may be electrically connected.

The power semiconductor device according to various embodiments of the present specification may further include an insulating layer, wherein the insulating layer may surround the second electrode and expose a portion of the lower portion thereof.

The power semiconductor device according to various embodiments of the present specification may further include an insulating layer, wherein the insulating layer may completely surround the gate electrode.

The power semiconductor device according to various embodiments of the present specification may further include a bonding layer, wherein the bonding layer may be in direct contact with the second semiconductor layer and the first semiconductor layer.

According to the power semiconductor device according to various embodiments of the present specification, the bonding layer may be in direct contact with the insulating layer below the gate electrode.

The power semiconductor device according to various embodiments of the present specification may further include a protective layer, wherein the protective layer may be located between the bonding layer and the insulating layer.

The power semiconductor device according to various embodiments of the present specification may further include a second source layer, wherein the second source layer may be located between the second semiconductor layer and the second electrode.

According to the power semiconductor device according to various embodiments of the present specification, the second source layer may have the first conductivity type.

According to the power semiconductor device according to various embodiments of the present specification, a thickness of the insulating layer disposed below the gate electrode may be larger than a thickness of the insulating layer disposed on side surfaces of the gate electrode.

According to a power semiconductor device according to embodiments, by additionally arranging a protective layer and/or a bonding layer under a gate electrode and adjusting the electric field distribution under the gate electrode, it is possible to improve electrical and physical stability.

According to the power semiconductor device according to the embodiments, by increasing a density of a channel through a plurality of closed trench gate structures, it is possible to minimize an increase in resistance, thereby reducing energy loss.

However, effects obtainable from the present specification are not limited to the above-described effects, and other effects that are not mentioned will be able to be clearly understood by those skilled in the art to which the present specification pertains based on the following description.

Although the embodiments of the present disclosure have been described above with reference to the accompanying drawings, those skilled in the art to which the present disclosure pertains will be able to understand that the above-described technical configuration of the present disclosure can be carried out in other specific forms without changing the technical spirit or essential features thereof. Accordingly, it should be understood that the above-described embodiments are illustrative and not restrictive in all respects. In addition, the scope of the present disclosure is described by the claims to be described below rather than the detailed description. In addition, the meaning and scope of the claims and all changed or modified forms derived from the equivalent concept should be construed as being included in the scope of the present disclosure.

What is claimed is:

1. A power semiconductor device comprising:
a first electrode;
a semiconductor layer on the first electrode;
a second electrode on the semiconductor layer; and
a plurality of gate electrodes on the semiconductor layer,
wherein the semiconductor layer includes
a first semiconductor layer of a first conductivity type on the first electrode, and
a second semiconductor layer of a second conductivity type between the first semiconductor layer and the second electrode,
the second electrode includes
a 2-1 electrode extending in a first direction, and
a plurality of 2-2 electrodes spaced apart from each other in the first direction,
the second semiconductor layer or the first semiconductor layer includes a trench region,
the trench region is disposed between the plurality of 2-2 electrodes, and
the gate electrodes are disposed in the trench region.

2. The power semiconductor device of claim 1, wherein the first semiconductor layer and the second semiconductor layer include silicon carbide (SiC).

3. The power semiconductor device of claim 1, wherein the first conductivity type is an N type and the second conductivity type is a P type.

4. The power semiconductor device of claim 1, wherein the first semiconductor layer includes a first layer and a second layer on the first layer, and a doping concentration of the first layer is higher than a doping concentration of the second layer.

5. The power semiconductor device of claim 1, wherein the second semiconductor layer includes a third layer and a first source layer between the third layer and the second electrode, the first source layer has the second conductivity type, and a doping concentration of the third layer is lower than a doping concentration of the first source layer.

6. The power semiconductor device of claim 1, wherein the 2-1 electrode and the plurality of 2-2 electrodes are electrically connected.

7. The power semiconductor device of claim 1, further comprising an insulating layer, wherein the insulating layer surrounds the second electrode and exposes a portion of a lower portion thereof.

8. The power semiconductor device of claim 1, further comprising an insulating layer, wherein the insulating layer completely surrounds the gate electrodes.

9. The power semiconductor device of claim 8, further comprising a bonding layer, wherein the bonding layer is in direct contact with the second semiconductor layer and the first semiconductor layer.

10. The power semiconductor device of claim 9, wherein the bonding layer is in direct contact with the insulating layer below the gate electrodes.

11. The power semiconductor device of claim 9, further comprising a protective layer, wherein the protective layer is located between the bonding layer and the insulating layer.

12. The power semiconductor device of claim 1, further comprising a second source layer, wherein the second source layer is located between the second semiconductor layer and the second electrode.

13. The power semiconductor device of claim 12, wherein the second source layer has the first conductivity type.

14. The power semiconductor device of claim 8, wherein a thickness of the insulating layer disposed below the gate electrode is larger than a thickness of the insulating layer disposed on side surfaces of the gate electrode.
